(19) United States
(12) Patent Application Publication
(10) Pub. No.: US 2015/0129989 A1
(43) Pub. Date: May 14, 2015

(54) GATE INSULATING LAYER AND METHOD FOR FORMING THE SAME

(71) Applicant: EverDisplay Optronics (Shanghai) Limited, Shanghai (CN)

(72) Inventors: Wei-ting CHEN, Shanghai (CN); Chia-chi HUANG, Shanghai (CN); Chunchieh HUANG, Shanghai (CN); Youyuan HU, Shanghai (CN)

(21) Appl. No.: 14/463,244

(22) Filed: Aug. 19, 2014

(30) Foreign Application Priority Data
Nov. 13, 2013 (CN) 201310566294.X

(51) Int. Cl. H01L 29/51; H01L 21/02

(52) U.S. Cl. CPC H01L 29/518; H01L 21/02274; H01L 29/512; H01L 21/0217
USPC 257/411; 438/763

(57) ABSTRACT

The present disclosure provides A gate insulating layer comprising: a first silicon nitride film having a first thickness and a first content of N—H bonds; a second silicon nitride film having a second thickness and a second content of N—H bonds, disposed on the first silicon nitride film; and a third silicon nitride film having a third thickness and a third content of N—H bonds, disposed on the second silicon nitride film; wherein both the first thickness and the third thickness are less than the second thickness, both the N—H bonds in the first content and the third content are less than that in the second N—H bonds content, and a difference of the N—H bonds between the third content and the first content is no less than 5%. The present disclosure also provides a method for forming the above gate insulating layer.

### CROSS REFERENCE TO RELATED APPLICATIONS

The present application claims priority under 35 U.S.C. §119 to Chinese Patent Applications No. 201310566294.X, filed on Nov. 13, 2013, the entire contents of which are incorporated herein by reference.

### TECHNICAL FIELD

The present disclosure generally relates to the field of semiconductor, and more particularly to a gate insulating layer and a method for fabricating the same.

### BACKGROUND

Currently, flat panel displays, such as liquid crystal display devices, organic electroluminescent display devices, etc., generally operate in an active matrix drive mode, and output signals to pixel electrodes through thin film transistors (TFT) of drive circuit portions that serve as switching elements. A common thin film transistor generally includes: an insulating substrate, a gate layer, a gate insulating layer, an active semiconductor layer and a source/drain electrode layer. During the production process, each layer in the thin film transistor needs to be patterned through a plurality of etching process. For the gate insulating layer, a dry etching such as a reactive ion etching or a plasma etching is generally adopted to perform an anisotropic etching, and a sidewall profile having a slope shape is formed after the etching. It is desirable that an etching angle θ which is an angle between a side surface portion and a bottom surface portion of the etched slope-shaped gate insulating layer reaches 40˜100°, which can prevent cracks generated in an active semiconductor growth layer above the gate insulating layer and crawling growths occurring in the bottom portion, and facilitate forming a good surface flatness for a semiconductor growth layer.

Currently, the gate insulating layer in the thin film transistor is generally constituted of a silicon nitride film and a silicon oxide film. For example, CN101300681A discloses a gate insulating layer having a double-layer structure of a silicon nitride film/a silicon nitride film, to overcome a problem of lowering a breakdown voltage when a gate insulating layer constituted of a single layer of a silicon oxide film becomes a thin film. However, the silicon oxide film and the silicon nitride film are heterogeneous films and the etching rates are different. Therefore, an undercut may occur during the etching of such a gate insulating layer having a double-layer structure of a silicon nitride film/a silicon nitride film, which adversely affects a growth of subsequent films.

Thus, there still needs an improved gate insulating layer which is capable of achieving a desirable etching angle after the etching process, to facilitate the growth of the subsequent films, and also keeps dielectric properties at the same time, so as to improve the performance and quality of the thin film transistor.

### SUMMARY

In order to, in part, solve the problems in the Background, in the present disclosure, based on a relationship between etching rates and compactness of material, and a relationship between compactness of silicon nitride film and contents of N—H-bonds therein, a gate insulating layer is formed with a stack structure of three layers of silicon nitride films among which each film has a different content of N—H-bonds, i.e. a different compactness. Wherein, the middle silicon nitride film which is the main body is relatively loose to keep production efficiency, so a compactness difference exists between the upper layer silicon nitride film and the lower layer silicon nitride film, resulting different etching rates, thereby a desirable etching angle may be achieved.

According to a first aspect of the embodiments of the present disclosure, a gate insulating layer is provided, which includes: a first silicon nitride film having a first thickness and a first content of N—H bonds; a second silicon nitride film having a second thickness and a second content of N—H bonds, disposed on the first silicon nitride film; and a third silicon nitride film having a third thickness and a third content of N—H bonds, disposed on the second silicon nitride film; wherein both the first thickness and the third thickness are less than the second thickness, both the N—H bonds in the first content and the third content are less than that in the second N—H bonds content, and a difference of the N—H bonds between the third content and the first content is no less than 5%.

According to a second aspect of the embodiments of the present disclosure, a method for forming a gate insulating layer is provides, which includes: sequentially depositing a first silicon nitride film, a second silicon nitride film and a third silicon nitride film respectively with a first power, a second power and a third power, and both the first power and the third power being less than the second power, a difference between the third power and the first power being no less than 1000 W, so as to fabricate the gate insulating layer by sequentially stacking the formed first silicon nitride film, second silicon nitride film and third silicon nitride film.

According to a third aspect of the embodiments of the present disclosure, a method for forming a gate insulating layer is provided, which includes: sequentially depositing a first silicon nitride film, a second silicon nitride film and a third silicon nitride film respectively with a first feedstock gas ratio, a second feedstock gas ratio and a third feedstock gas ratio, so as to fabricate the gate insulating layer by sequentially stacking the formed first silicon nitride film, second silicon nitride film and third silicon nitride film.

In the present disclosure, a stack structure of three layers of silicon nitride films is formed by changing the filming structure of the gate insulating layer. A gate insulating layer having three different layers of films of a compact silicon nitride film—a loose silicon nitride film—a compact silicon nitride film is formed by adjusting filming process conditions to control the contents of N—H-bonds in the three layers of silicon nitride films, so as to changing the filming qualities of the three layers of silicon nitride films. In the present disclosure, the second silicon nitride film which is in the middle and is relatively loose has a relatively large thickness and serves as the main body of the gate insulating layer to keep production efficiency. The first and the third silicon nitride films which are at outer sides and relatively compact have a relatively small thickness, and the compactness of the first silicon nitride film is larger than the compactness of the third silicon nitride film, and particularly, a difference between the contents of N—H-bonds of both is above 5%, such that the etching rate of the first silicon nitride film is slower than that of the third silicon nitride film. Thus, during the etching, a desirable etching angle (40˜60°) may be achieved to avoid an occurrence of an undercut. In addition, the three layers of silicon nitride films of the present disclosure may be sequentially formed at once in the same chamber with the same feedstock gas, so the process may be simple, the cost may be low, and since the three layers are all silicon nitride films, the interface property may be excellent.

Other features and advantages of the present disclosure will be explained in the following description, and part of which will become obvious from the description, or may be understood by carrying out the present disclosure. Purposes and other advantages of the present disclosure may be achieved and obtained by structures or steps particularly pointed out in the written description, claims and the accompanying drawings.

It should be appreciated that, the above general description and the following detailed description are merely exemplary, and do not limit the disclosure.

### BRIEF DESCRIPTION OF THE DRAWINGS

The accompany drawings which constitute a part of the description, are provided for a better understanding of the present disclosure, and serve to explain the present disclosure together with embodiments of the present disclosure, but do not constitute a limitation to the present disclosure, in which:

FIG. 1 is a schematic structural view of a gate insulating layer of the present disclosure;

FIG. 2 is a flow chart of a method for fabricating the gate insulating layer according to a first embodiment of the present disclosure; and

FIG. 3 is a flow chart of a method for fabricating the gate insulating layer according to a second embodiment of the present disclosure.

### DETAILED DESCRIPTION

In order to make the objects, the technical solutions and advantages more clear, the present disclosure will be described in further detail with reference to the embodiments and the accompany drawings. The protective scope of the present disclosure is not limited to the following embodiments, and these embodiments are set forth merely for illustration purpose and do not limit the present disclosure by any means.

A gate insulating layer is provided by the present disclosure, which may have an improved etching angle. As shown in FIG. 1, the gate insulating layer includes: a first silicon nitride film having a first thickness and a first content of N—H bonds; a second silicon nitride film having a second thickness and a second content of N—H bonds, disposed on the first silicon nitride film; a third silicon nitride film having a third thickness and a third content of N—H bonds, disposed on the second silicon nitride film, wherein both the first thickness of the first silicon nitride film and the third thickness of the third silicon nitride film are less than the second thickness of the second silicon nitride film, both the N—H bonds in the content in the first silicon nitride film and the N—H bonds in the content in the third silicon nitride film are less than the N—H bonds in the content in the second silicon nitride film, and a difference between the N—H bonds in the content in the third silicon nitride film and the N—H bonds in the content in the first silicon nitride film is no less than 5%.

According to the embodiments of the present disclosure, silicon nitride having a high dielectric constant is used as material for forming the gate insulating layer, and the silicon nitride is generally etched by a dry etching such as a reactive ion etching or a plasma etching, to perform an anisotropic etching, and a sidewall profile having a slope shape is formed after the etching. It is desirable that an etching angle θ which is an angle between a side surface portion and a bottom surface portion of the etched slope-shaped gate insulating layer reaches 40˜100°, which can prevent cracks generated in an active semiconductor growth layer above the gate insulating layer and crawling growths occurring in the bottom portion, and facilitate forming a good surface flatness for a semiconductor growth layer. For the same material, an etching rate is in an inverse proportion to a compactness of the material, that is, the higher the compactness of the material is, the lower the etching rate is. The compactness of the material is closely related to the content of N—H bonds in the material. In one embodiment of the present disclosure, the silicon nitride film is prepared by using methyl silane, ammonia gas and nitrogen gas as feedstock gas for example. The prepared silicon nitride film generally contains N—H bonds, Si—H bonds, Si—Si bonds and Si—N bonds, and the N—H bonds and the Si—H bonds which are long-range bonds are of poor stability with respect to the Si—Si bonds and the Si—N bonds which are short-ranged bonds. Therefore, the higher the content of N—H bonds or N—H bonds is, the lower the compactness of the silicon nitride film is. Based on the correlation between the etching rate and the compactness of the material and the correlation between the compactness of the silicon nitride film and the content of N—H bonds in the film, in the present disclosure, three layers of silicon nitride films having different compactness may be formed by adjusting the contents of N—H bonds in the three layers of silicon nitride films, such that the second silicon nitride film in the middle part as a main body portion has a relatively high content of N—H bonds, for example greater than 20%, and has a relatively loose film to keep production efficiency. While the first silicon nitride film has a content of N—H bonds, for example less than 10%, the third silicon nitride film has a content of N—H bonds, for example less than 15%, and the difference between the contents of N—H bonds of both is above 5%. Therefore, the first silicon nitride film has a higher compactness than that of the third silicon nitride film, and thus the third silicon nitride film has an etching rate greater than that of the first silicon nitride film. Accordingly, during the etching process, the gate insulating layer formed by stacking the three layers of silicon nitride films having the above difference in compactness may easily achieve an etching angle of 40˜100°, particularly 40˜60°.

A method for forming the above gate insulating layer is also provided by the present disclosure. According to the present disclosure, the three layers of silicon nitride films are all formed by a chemical vapor deposition (CVD) method. Specifically a low pressure chemical vapor deposition method, a thermal vapor deposition method, a catalytic chemical vapor deposition method, a plasma enhanced chemical vapor deposition method and the like may be adopted, and for example the plasma enhanced chemical vapor deposition method is adopted. The plasma enhanced chemical vapor deposition method (PECVD) is a commonly used technique for preparing a low-temperature film, which combines glow discharge and chemical vapor deposition and is especially suitable for preparation of semiconductor thin films and compound thin films. The basic process of the PECVD is to use low temperature plasmas as an energy source, place a substrate on a glow discharge cathode, feed proper gas as reaction feedstock gas to conduct a series of chemical reactions and plasma reactions and form a series of thin films on the surface of the substrate. A PECVD device has a multi-channel gas access means, and may simultaneously guide various gases into reaction chambers of the device for the growth of the doped amorphous silicon thin film. The gate insulating layer and the three layers constituting a stack structure according to the present disclosure are all silicon nitride films, therefore, for example it is to sequentially form the films at once by using the same feedstock gas in the same reaction chamber through the PECVD method.

As the feedstock gas for forming the silicon nitride film, NH₃, NH₂H₂N, N₂, etc., preferably NH₃ and N₂ may be used as a nitrogen source gas, and SiH₄, Si₂H₆, SiCl₄, SiHCl₃, SiH₂Cl₂, SiH₃Cl₃, SiF₄, etc., for example SiH₄ may be used as silicon source gas.

The contents of N—H bonds in the three layers of silicon nitride films may be made different to form film layers having different compactness by adjusting a parameter of the process, specifically, by using the same type and ratio of feedstock gases and the same temperature of the deposition process and adjusting the power to realize the control of the contents of N—H bonds, or by using the same type of feedstock gases and the same temperature of the deposition process and power and adjusting the ratio of feedstock gases to realize the control of the contents of N—H bonds.

In embodiments of the present disclosure, the ratio of the first feedstock gas, the ratio of the second feedstock gas and the third feedstock gas are molar ratios of the feedstock gases, flow rates as mentioned are all volume flow ratio (i.e., mole ratio).

Terms used in the present disclosure should be interpreted as the meanings commonly understood by those skilled in the art, unless otherwise defined.

Hereinafter, the present disclosure is further explained with reference to embodiments.

### EMBODIMENTS

### A First Embodiment

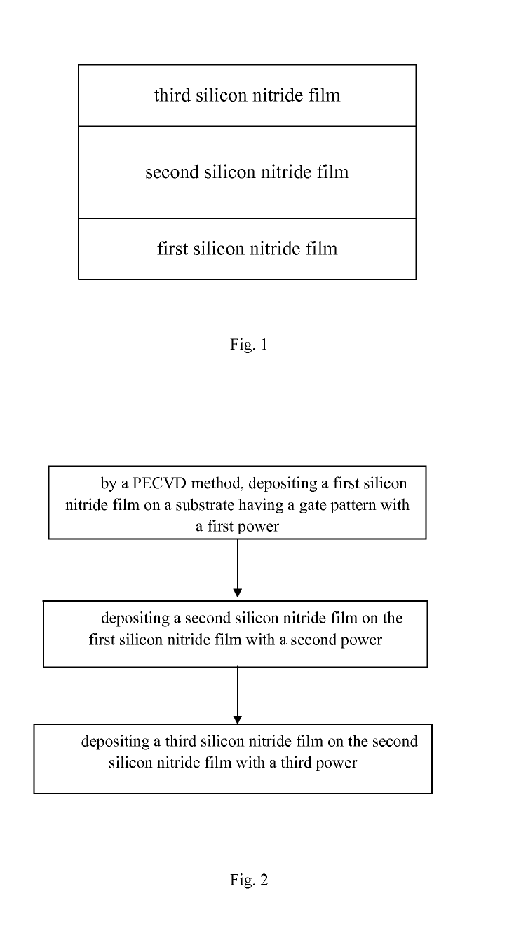

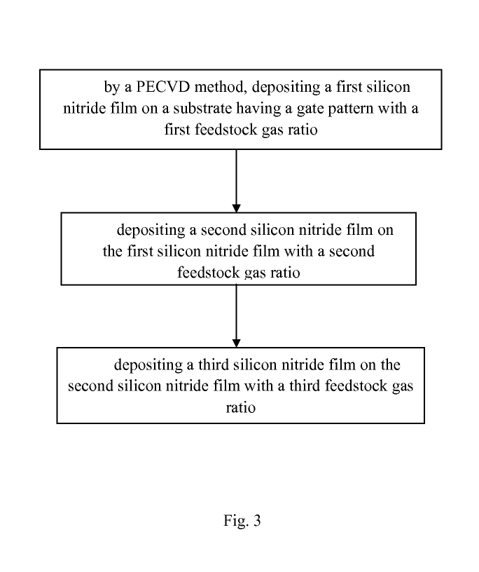

In this embodiment, a gate insulating layer of the present disclosure is fabricated through a PECVD method by using the same type and ratio of feedstock gases and the same temperature of the deposition process and by adjusting the power to realize the control of the contents of N—H bonds. As shown in FIG. 2, steps of the specific process are as follows.

In a vacuum chamber, by using a radio frequency source with 13.56 MHz of radio frequency, low-temperature plasmas are generated as reaction energy source gas. Methyl silane, ammonia and nitrogen as reaction gases are fed through the multi-channel gas access means. The flow rate ratio of methyl silane and ammonia is set to 0.2, the temperature of the deposition process is set to 360° C. With a first power of 1000 W, a first silicon nitride film with 80 Å of thickness is deposited on a glass substrate having a gate pattern.

In the same chamber, by keeping the above process conditions and only changing the radio frequency power, and with a second power of 5000 W, a second silicon nitride film with 600 Å of thickness is sequentially deposited on the formed first silicon nitride film.

Subsequently, in the same chamber, by keeping the above process conditions and changing only the radio frequency power, and with a third power of 2000 W, a third silicon nitride film with 80 Å of thickness is sequentially deposited on the formed second silicon nitride film. Thereby, the gate insulating layer of the present disclosure is fabricated.

Bonding states of elements in the first silicon nitride film, the second silicon nitride film and the third silicon nitride film of the above gate insulating layer are analyzed with a Fourier transform infrared spectroscopy. Through the Fourier transform infrared spectroscopy, the thickness of N—H bonds in each film is determined, and the ratio of the content of N—H bonds in each film is calculated accordingly as: 10% in the first silicon nitride film, 22% in the second silicon nitride film and 16% in the third silicon nitride film. Thus, in the gate insulating layer formed according to the method of the present embodiment, the content of N—H bonds in the first silicon nitride film is less than that of the third silicon nitride film, and the difference between both is greater than 5%. The gate insulating layer is further etched with reactive ions and its etching angle is measured as 55°.

### The Second Embodiment

In this embodiment, a gate insulating layer of the present disclosure is fabricated through a PECVD method by using the same type of feedstock gases and the same temperature of the deposition process and power and by adjusting the ratio of feedstock gases to realize the control of the contents of N—H bonds. As shown in FIG. 3, steps of the specific process are as follows.

In the vacuum chamber, by using a radio frequency source with 13.56 MHz of radio frequency, low-temperature plasmas are generated as reaction energy source gas. The temperature of the deposition process is set to 360° C., and the radio frequency power is set to 4000 W. Methyl silane, ammonia and nitrogen as reaction gases are fed through the multi-channel gas access means. The flow rate ratio between methyl silane and ammonia, i.e. a first feedstock gas ratio is set to 1. Then a first silicon nitride film with 80 Å of thickness is deposited on a glass substrate having a gate pattern.

In the same chamber, by keeping the above process conditions, only changing the flow rate ratio between methyl silane and ammonia and setting it to be a second feedstock gas ratio of 0.1, a second silicon nitride film with 600 Å of thickness is sequentially deposited on the formed first silicon nitride film.

Subsequently, in the same chamber, by keeping the above process conditions, only changing the flow rate ratio between methyl silane and ammonia and setting it to be a third feedstock gas ratio of 0.2, a third silicon nitride film with 80 Å of thickness is sequentially deposited on the formed second silicon nitride film. Thereby, the gate insulating layer of the present disclosure is fabricated.

Bonding states of elements in the first silicon nitride film, the second silicon nitride film and the third silicon nitride film of the above gate insulating layer are analyzed with a Fourier transform infrared spectroscopy. Through the Fourier transform infrared spectroscopy, the thickness of N—H bonds in each film is determined, and the ratio of the content of N—H bonds in each film is calculated accordingly as: 12% in the first silicon nitride film, 24% in the second silicon nitride film and 18% in the third silicon nitride film, respectively. Thus, in the gate insulating layer formed according to the method of the present embodiment, the content of N—H bonds in the first silicon nitride film is less than that of the third silicon nitride film, and the difference between the both is greater than 5%. The gate insulating layer is further etched with reactive ions and its etching angle is measured as 60°.

In summary, three layers of silicon nitride films with different contents of N—H bonds are sequentially formed by adjusting process parameters, so as to constitute a gate insulating layer. Due to differences in internal compactness, etching rates are different, thereby a slope-shaped side surface profile may be formed with a desirable etching angle.

Although the exemplary embodiments of the present disclosure have been illustrated in the above, it should be noticed that, various alteration and modification may be made without departing the scope of the present disclosure, which is defined by the claims. In addition, although elements of the present disclosure may be described or prescribed in a single form, multiple forms may also be devised, unless the single form is explicitly prescribed.

The objects, technical solutions and advantageous effects of the present disclosure have been explained in a further detail with the above specific embodiments. It should be appreciated that, the above are merely specific embodiments of the present disclosure, and not used to limit the scope of the present disclosure. Any alteration, equivalent replacement, modification and the like within the spirit and principle of the present disclosure should be embraced in the protection scope of the present disclosure.

What is claimed is:

1. A gate insulating layer comprising:
a first silicon nitride film having a first thickness and a first content of N—H bonds;
a second silicon nitride film having a second thickness and a second content of N—H bonds, disposed on the first silicon nitride film; and
a third silicon nitride film having a third thickness and a third content of N—H bonds, disposed on the second silicon nitride film;
wherein
both the first thickness and the third thickness are less than the second thickness,
both the N—H bonds in the first content and the third content are less than that in the second N—H bonds content, and
a difference of the N—H bonds between the third content and the first content is no less than 5%.

2. The gate insulating layer according to claim 1, wherein
the N—H bonds in the first content is less than 10%, the N—H bonds in the second content is higher than 20%, the N—H bonds in the third content is less than 15%.

3. The gate insulating layer according to claim 1, wherein
each of the first thickness and the third thickness is 10˜500 Å, and the second thickness is 500˜1000 Å.

4. The gate insulating layer according to claim 1, wherein
an etching angle of the gate insulating layer is between 40° and 60°.

5. A method for forming a gate insulating layer comprising:
sequentially depositing a first silicon nitride film, a second silicon nitride film and a third silicon nitride film respectively with a first power, a second power and a third power, and both the first power and the third power being less than the second power, a difference between the third power and the first power being no less than 1000 W, so as to fabricate the gate insulating layer by sequentially stacking the formed first silicon nitride film, second silicon nitride film and third silicon nitride film.

6. The method according to claim 5, wherein the feedstock gas is methyl silane, ammonia and nitrogen, and a flow rate ratio of ammonia and methyl silane is 0.2 to 0.4.

7. The method according to claim 5, wherein a temperature of the deposition process is 340˜380° C.

8. The method according to claim 5, wherein the first power is 800˜1000 W, the second power is 3000˜5000 W, and the third power is 1500˜2000 W.

9. The method according to claim 5, wherein both a thickness of the first silicon nitride film and a thickness of the third silicon nitride film are less than that of the second silicon nitride film.

10. The method according to claim 9, wherein each of the thickness of the first silicon nitride film and the thickness of the third silicon nitride film is 10˜500 Å, and the thickness of the second silicon nitride film is 500˜1000 Å.

11. A method for forming a gate insulating layer comprising:
sequentially depositing a first silicon nitride film, a second silicon nitride film and a third silicon nitride film respectively with a first feedstock gas ratio, a second feedstock gas ratio and a third feedstock gas ratio, so as to fabricate the gate insulating layer by sequentially stacking the formed first silicon nitride film, second silicon nitride film and third silicon nitride film.

12. The method according to claim 11, wherein the power is 3000˜5000 W.

13. The method according to claim 11, wherein a temperature of the deposition is 340˜380° C.

14. The method according to claim 11, wherein the feedstock gas is methyl silane, ammonia and nitrogen.

15. The method according to claim 14, wherein the first feedstock gas ratio that is a molar ratio between methyl silane and ammonia is between 0.8 and 1, the second feedstock gas ratio that is a molar ratio between methyl silane and ammonia is between 0.05 and 0.1, and the third feedstock gas ratio that is a molar ratio between methyl silane and ammonia is between 0.2 and 0.4.

16. The method according to claim 15, wherein the first feedstock gas ratio that is a molar ratio between methyl silane and ammonia equals to 1, the second feedstock gas ratio that is a molar ratio between methyl silane and ammonia equals to 0.1, and the third feedstock gas ratio that is a molar ratio between methyl silane and ammonia equals to 0.2.

17. The method according to claim 11, wherein both a content of N—H bonds in the first silicon nitride film and a content of N—H bonds in the third silicon nitride film are less than a content of N—H bonds in the second silicon nitride film, and a difference between the content of N—H bonds in the third silicon nitride film and the content of N—H bonds in the first silicon nitride film is no less than 5%.

18. The method according to claim 17, wherein the content of N—H bonds in the first silicon nitride film is less than 10%, the content of N—H bonds in the second silicon nitride film is higher than 20%, the content of N—H bonds in the third silicon nitride film is less than 15%, and the difference between the content of N—H bonds in the first silicon nitride film and the content of N—H bonds in the third silicon nitride film is no less than 5%.

19. The method according to claim 11, wherein both a thickness of the first silicon nitride film and a thickness of the third silicon nitride film are less than that of the second silicon nitride film.

20. The method according to claim 19, wherein each of the thickness of the first silicon nitride film and the thickness of the third silicon nitride film is 10˜500 Å, and the thickness of the second silicon nitride film is 500˜1000 Å.
